(19) United States
(12) Patent Application Publication
(10) Pub. No.: US 2008/0115038 A1
(43) Pub. Date: May 15, 2008

(54) Dynamic early termination of iterative decoding for turbo equalization

(75) Inventors: Hiau Choon Kee, Singapore (SG); Ming Jin, Lake Forest, CA (US); Zhen Yu Sun, Singapore (SG); Myint Ngwe, Singapore (SG)

Correspondence Address: SEAGATE TECHNOLOGY LLC C/O WESTMAN;CHAMPLIN & KELLY, P.A., SUITE 1400, 900 SECOND AVENUE SOUTH, MINNEAPOLIS, MN, 55402-3319, US

(73) Assignee: Seagate Technology LLC, Scotts Valley, CA (US)

(21) Appl. No.: 11/589,264

(22) Filed: Oct. 26, 2006

(51) Int. Cl. H03M 13/00

(52) U.S. Cl. 714/760

(57) ABSTRACT

A method and apparatus for selectively terminating turbo equalization is disclosed. At least two iterations of turbo equalization are performed. The number of errors corrected between the first iteration and the second iteration are calculated. In one embodiment, if the sign of corresponding bits in the data block is different between the two iterations, an error was corrected. If the number of errors corrected is greater than a stopping value, a subsequent iteration of turbo equalization is performed. If the number of errors corrected is less than or equal to the stopping value, then associated values for the data are output and the turbo equalization is terminated.

### FIELD OF THE DISCLOSURE

The present disclosure relates generally to communication channels, and more particularly but not by limitation to managing iterations of turbo equalization for error correction.

### BACKGROUND OF THE DISCLOSURE

In the field of digital communications, digital information is typically prepared for transmission through a channel by encoding it. The encoded data is then used to modulate a transmission to the channel. A transmission received from the channel is then demodulated and decoded to recover the original information.

Encoding the digital data serves to improve communication performance so that the transmitted signals are less corrupted by noise, fading, or other interference associated with the channel. The term “channel” can include media such as transmission lines, wireless communication and information storage devices such as magnetic, optical or magneto-optical disc drives. In the case of information storage devices, the signal is stored in the channel for a period of time before it is accessed or received.

There are several types of error correction codes (ECCs) that have been developed for recovering lost data. Error correction methods are typically chosen depending on the error characteristics of the transmission or storage medium, such that these errors are detected and corrected with a minimum of redundant data stored or sent. Typically, in data storage systems, block ECC codes are used, such as Hamming codes or Reed-Solomon codes. These codes transform a block of original data bits into a longer block of encoded bits in such a way that errors up to a threshold in each block of data can be detected and corrected.

Hamming codes allow for detection of multiple errors in the bits that comprise a word. A word is merely a set number of bits that represent data. A word can include any number of bits, such as 8, 16 or 32 bits. A Hamming code is able to correct errors of one bit, but cannot correct errors of more than one bit in the word. As word length has increased with the use of 64 and 128 bit words, for example, there is an increase in the probability of errors occurring in the words. The increase in probability for errors increases the need for more error correction, which cannot be provided by a Hamming code.

Reed-Solomon coding has historically been used in areas where there is a high probability of errors occurring, where multiple bits or even bytes of data are lost. A Reed-Solomon code provides the ability to detect and correct multiple errors in blocks of data.

The error correction coding schemes such as the ones discussed above are getting more and more sophisticated. This sophistication helps to achieve lower error rates (such as sector error rates “SERs” in a storage system) and enhances overall performance. An example of an improvement to error coding techniques is known as “turbo equalization” or “turbo codes”. Examples of turbo equalization are discussed in, T. Souvignier et al., “Turbo Decoding for PR4: Parallel Versus Serial Concatenation,” in Proc. 1999 Int. Conf. Commun., vol. 3, June 1999, p. 1638-1642 vol. 3, and T. Souvignier et al., “Turbo Decoding for Partial Response Channels,” in IEEE Trans. on Comm., vol. 48, no. 8, August 2000. p. 1297-1308. Turbo equalization combines iterative decoding, such as between an ECC module and a detector module, and is a tool that is currently being adopted in the data storage industry to ensure that desired SER performance can be achieved.

With “iterative” (or “turbo”) decoding, the data is processed multiple times in the detector. In a typical iterative decoder, special coding (parity and interleaving are two of several options) is introduced before the data is transmitted to the channel. When the data is received from the channel, the data runs through a “soft decoder”, which produces quality “soft” information (such as a log likelihood ratio) about each bit decision it makes. The soft decisions are transferred to a block that resolves the parity based on the hard and soft information. This step is often implemented with a technique called “message passing.” Once the message passing is complete, both the soft and hard information have been altered and hopefully improved. This updated information is passed back to the soft decoder where the signal is detected again. Finally, the hard and soft detector output is sent back to the parity resolver, where the hard and soft information is once again improved. This iteration process may continue any number of times. Practically, the number of iterations is limited by the time that system has to deliver the data to the user. The result is an increased confidence or reliability of the detected data.

By iteratively exchanging soft values of log likelihood ratios for the received bits of data, it has been shown that a simulated result can approach the Shannon limit discussed in C. Berrou, A. Glavieux, and P. Thitimajshima, “Near Shannon limit error-correcting coding and decoding: turbo codes,” in Proc., IEEE Int. Conf. on Comm. (Geneva, Switzerland, May 1993), p. 1064-1070.

While turbo equalization provides excellent performance, a drawback of turbo equalization is that extra power and computing time are consumed during each iteration since turbo equalization typically involves extensive calculations. The extra power and computing time can be a concern in certain applications, such as hard disc drives and probe storage devices, especially those having very small form factors. For example, power consumption can be a crucial issue for storage systems used in digital cameras, personal digital assistants (PDAs) and other. Thus there is a desire for a simple and useful technique to address this problem.

One or more embodiments of the present invention provide solutions to these and other problems, and offer other advantages over the prior art. SUMMARY

An embodiment of the disclosure is directed to a process for iterative decoding an output until a number of errors corrected between subsequent iterations reaches a predetermined stopping value.

Another embodiment of the disclosure is directed to a decoder including an iterative decode function, which terminates as a function of a number of errors corrected between subsequent iterations of the decode function.

Another embodiment of the disclosure is directed to a data storage device. The data storage device includes a storage medium, a write channel and a read channel. The write channel is coupled to communicate with the storage medium. The read channel is coupled to communicate with the storage medium and includes a decoder that has an iterative decode function, which terminates as a function of a number of errors corrected between subsequent iterations of the decode function.

Other features and benefits of one or more embodiments of the present disclosure will be apparent upon reading the following detailed description and review of the associated drawings.

### BRIEF DESCRIPTION OF THE DRAWINGS

FIG. 1 is an isometric view of a disc drive according to one embodiment.

FIG. 2 illustrates a typical turbo equalization model according to one embodiment.

FIG. 3 is a flow diagram illustrating a process for early termination of turbo equalization.

FIG. 4 is a flow diagram illustrating a process for determining a 6 between an nth iteration and an (n+1)^{th} iteration of the turbo equalization.

FIG. 5 is a block diagram illustrating a layout of a turbo equalizer according to an embodiment.

FIG. 6 is a plot illustrating mean of total error and mean of corrected error against iteration number for a turbo equalization procedure according to an embodiment of the present invention.

FIG. 7 is a plot illustrating sector error rates after different numbers of iterations for a turbo equalization having dynamic early termination, according to an embodiment of the present invention.

### DETAILED DESCRIPTION OF ILLUSTRATIVE EMBODIMENTS

One or more embodiments of the present invention relate to dynamic early termination of iterative decoding in turbo equalization procedures. Such procedures can be used with any communication channel in which early termination is useful, such as in data storage systems.

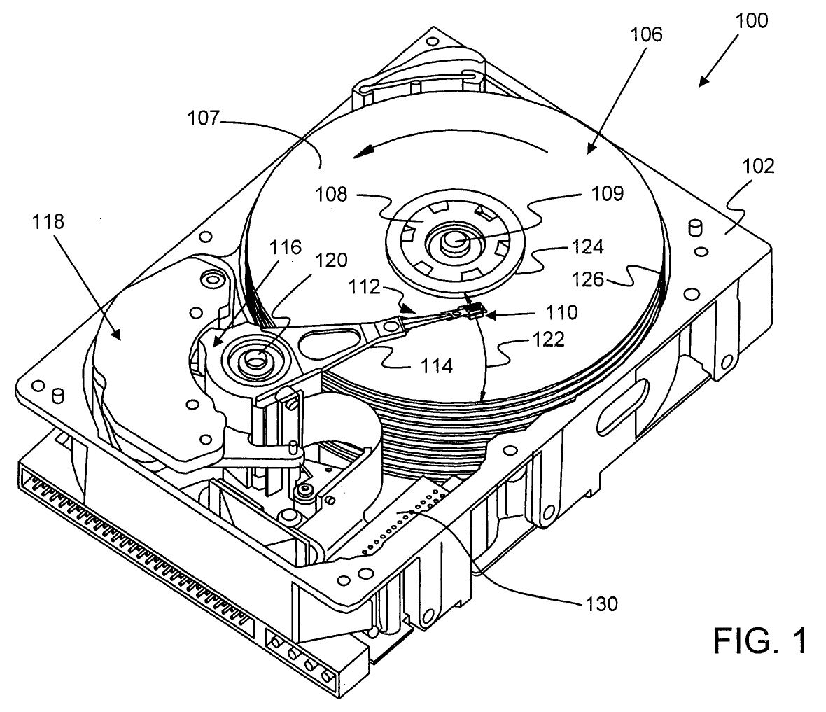

FIG. 1 is an isometric view of one type of data storage system in which an embodiment of the present invention is useful. In this embodiment, the data storage system includes a disc drive 100. Disc drive 100 forms a part of a communication channel in which the disc drive communicates with a host system (not shown). Disc drive 100 includes a housing with a base 102 and a top cover (not shown). Disc drive 100 further includes a disc pack 106, which is mounted on a spindle motor (not shown), by a disc clamp 108. Disc pack 106 includes a plurality of individual discs 107, which are mounted for co-rotation about central axis 109. Each disc surface has an associated head, which is mounted to disc drive 100 for communication with the disc surface. In the example shown in FIG. 1, heads 110 are supported by suspensions 112 which are in turn attached to track accessing arms 114 of an actuator 116. The actuator shown in FIG. 1 is of the type known as a rotary moving coil actuator and includes a voice coil motor (VCM), shown generally at 118. Voice coil motor 118 rotates actuator 116 with its attached heads 110 about a pivot shaft 120 to position heads 110 over a desired data track along an arcuate path 122 between a disc inner diameter 124 and a disc outer diameter 126. Voice coil motor 118 operates under control of internal (or external) circuitry 130.

The heads 110 and rotating disc pack 106 define a communications channel that can receive digital data and reproduce the digital data at a later time. In one embodiment, an encoder within internal circuitry 130 receives original user data, typically from a digital computer, and then encodes the data into successive code words according to a code. The encoded data is then used to modulate a write current provided to a write transducer in the head 110. The write transducer causes the modulated code words to be encoded on a magnetic layer in disc pack 106. At a later time, a read transducer in the head 110 recovers the successive modulated code words from the magnetic layer as a serial modulated read signal. Read circuitry within internal circuitry 130 demodulates the read signal into successive parallel code words. The demodulated code words are then decoded by a decoder within circuitry 130, which recovers the original user data for use by host system.

In one embodiment, the communication channel in disc drive 100 implements turbo equalization having dynamic early termination, as described in more detail below.

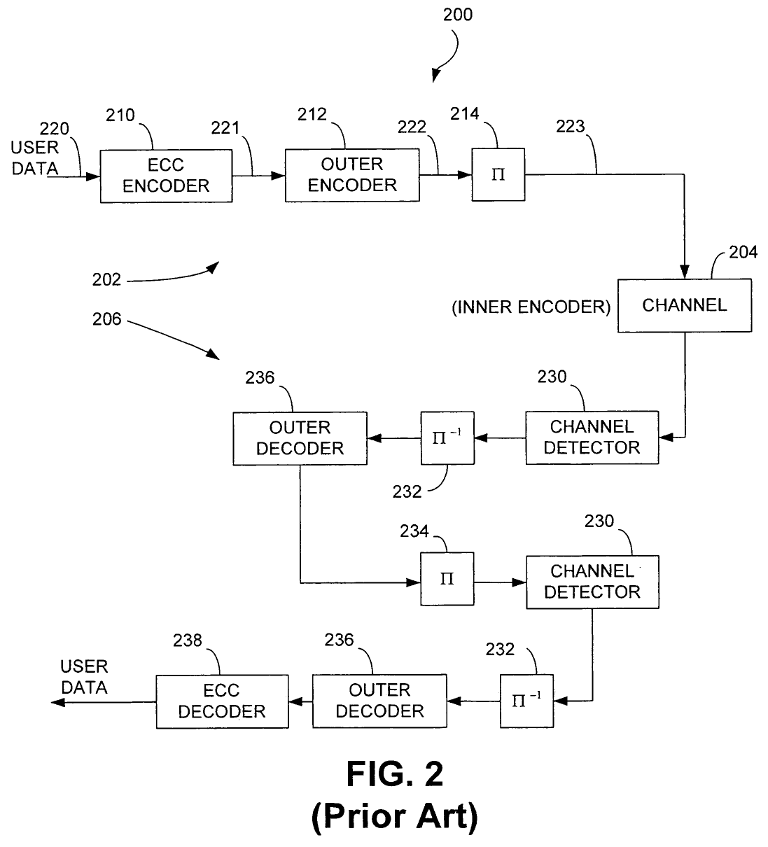

FIG. 2 is a block diagram illustrating a standard iterative encoding/decoding system 200 for a magnetic recording channel according to the prior art. System 200 includes a write (or transmitter) path 202, a channel (magnetic recording media) 204, and a read (or receiver) path 206. Write path 202 includes an ECC encoder 210, an outer encoder 212, and an interleaver 214. In one embodiment, ECC encoder 210 has a generator matrix of (1, g₂(D)/g₁(D)). However, other matrices can be used in alternative embodiments.

ECC encoder 210 receives successive user data words 220 and generates corresponding, multiple-bit symbols 221 at the output of the encoder. Each symbol includes the original data word plus one or more ECC parity bits. ECC symbols 221 are passed to outer encoder 212, which further encodes the ECC symbols into code words 222 having additional outer code parity bits, for example. The additional outer code can include an iterative or “turbo-product” code, for example. The code words 222 are concatenated and passed to interleaver 214, which pseudo-randomly shuffles the order of bits in the code word stream 223 in order to make reliability information gathered in the read channel more evenly distributed and independent of the bit order. The interleaved bit stream 223 is then transmitted to channel 204.

In this example, channel 204 includes a magnetic recording channel and acts as an inner encoder. The transmission (or write) part of channel 204 can include typical elements, such as a precoder, a modulator, etc. (these are at the encoding side, i.e., after interleaver 214), which prepare the bit stream for transmission through the channel (and storage in the channel in the case of a recording channel). The front end stages at the detection part of channel 204 can include a preamplifier, a timing circuit, an equalizer and others.

The output of channel 204 is coupled to read path 206, which includes a soft output channel detector 230, a de-interleaver 232, an interleaver 234, an outer decoder 236 and an ECC decoder 238. Essentially, the read path 206 has similar blocks as the write path 202 for undoing the effects of encoding in the write path. In this example of the prior art, channel detector 230 is a Soft Output Viterbi Algorithm (SOVA) detector, which removes inter-symbol interference (ISI) of the channel and therefore acts as an inner decoder. The received signal is first processed by front end circuits (not illustrated in FIG. 2), sampled, equalized and coupled to the input of SOVA detector 230. SOVA detector 230 produces soft (quality) information as to the likely state of each bit position in the received bit stream and provides the soft information to outer decoder 236 through de-interleaver 232. De-interleaver 212 reorders the soft information from the channel domain to a bit order corresponding to the parity domain (the order needed by outer decoder 236 and ECC decoder 238). De-interleaver 232 essentially applies the inverse of the shuffling operation performed by interleaver 214 such that the bits are in the same order as that produced at the output of encoder 212.

Outer decoder 236 decodes the outer code parity bits according to the soft information received from SOVA detector 230 and employs a message passing algorithm to produce its own soft information as to the reliability of each bit decision. Depending on whether the outer code parity bits match or do not match the data represented by the soft information produced by SOVA detector 230, outer decoder 236 can upgrade or degrade the reliability of the soft information for the corresponding bit positions. This soft information is compatible with that produced by SOVA detector 230. The soft information produced by outer decoder 236 is passed back to SOVA detector 230 through interleaver 234. Interleaver 234 re-interleaves the soft information into the bit order of the channel domain, where SOVA detector 230 detects the signal again. The SOVA detector 230 again makes decisions as to the likely state of each bit position and takes into account the extrinsic soft information provided by outer decoder 236 to produce new soft information as to each bit position, which is hopefully improved as compared to the first iteration. The new soft information is passed back to outer decoder 236, where the soft information is once again improved. This iteration process may continue any number of times. Practically, the number of iterations is limited by the time the system has to deliver the data to the user.

Once the iteration process has completed, a final “hard” decision is made based on the soft information whether each bit position is more likely a one or a zero. The final soft information is then converted to ones and zeros. The outer parity bits used by outer decoder 236 are discarded by decoder 236, and the remaining user data bits are passed through ECC decoder 238. ECC decoder 238 resolves the ECC parity bits to detect and/or correct any errors not corrected by the iterative detector formed by SOVA detector 230 and outer decoder 236. ECC decoder 238 then outputs respective user data words, which should correspond to the original user data words received by ECC encoder 210 at the input of the write path.

In turbo equalization is it important to determine a number of iterations (NOI) needed without wasting power and computing time, or degrading the performance. In order to achieve this, various early termination (ET) strategies have been developed. These strategies are based upon different indicators of the likelihood that a decoded data block is correct. The following are examples of commonly used ET strategy.

Comparison-based ET: This compares the decoder frames from two consecutive iterations. If the two frames are “close” by a certain measure, the data block is then unlikely to improve upon further iterations. A drawback of comparison-based ET is that the decision to stop the termination is not very reliable. In particular, the decoding can be terminated prematurely when further iterations would continue to improve the number of errors in the frame. This is especially noticeable when the frame length is small.

Cyclic Redundancy Check (CRC) code-based ET: This technique checks the CRC codes embedded in the turbo frames. If the decoded frame passes the CRC check, the decoder will stop the iteration. The reliability of the CRC-based ET depends on the number of CRC bits chosen since the probability of an incorrect frame passed the CRC check is approximated by 2^{-C}. For example, C=30 to 40, the contribution to the overall bit error rate of an incorrect frame slipping through the CRC check is negligible. However, long CRC bits increase the transmission overhead, particularly for small frames.

Signal to noise ratio (SNR) thresholding: The decoded results in each iteration of the turbo decoder are soft-output. For binary turbo codes, this means the decoder outputs are not simply −1 or 1 but instead are centered around −1 and 1 after proper scaling. This output pattern is very similar to binary phase shift keying (BPSK) signaling over the Gaussian channel, and thus can be modeled as such. It is observed that outputs from the decoder are “noisy” initially and become more and more concentrated to −1 and 1 as the iteration progresses. In other words, the signal to noise ratio of the decoder outputs improves with continued iterations. With SNR thresholding, the decoder terminates the iteration process when the calculated SNR from the decoded output exceeds a pre-selected threshold. Like comparison-based ET, SNR-thresholding saves power consumption with the disadvantage of degrading the bit error rate (BER). SNR thresholding allows a trade-off between the BER and power consumption. A lower SNR threshold decreases the average number of iterations but increases BER, and a higher SNR threshold does the converse. In other words, SNR thresholding is unable to reduce the power while holding the BER down. These and other early termination strategies are either not very reliable or not very effective or both.

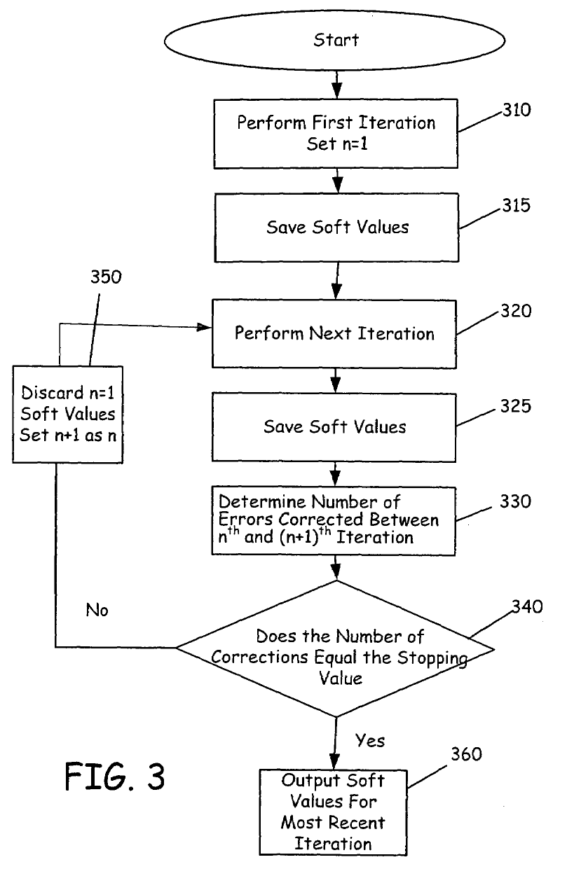

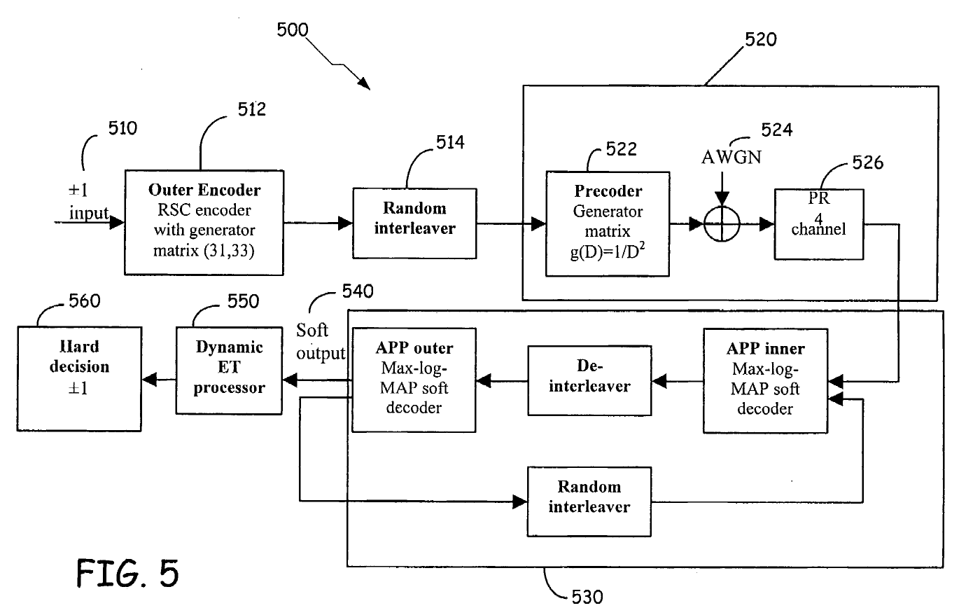

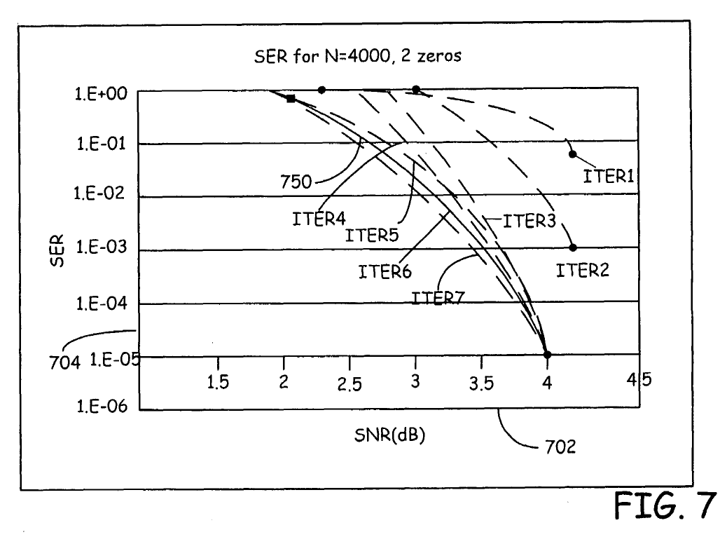

FIG. 3 is a flow diagram illustrating a process for turbo coding using a turbo coding architecture that delivers a more reliable dynamic ET strategy in order to achieve lower number of iterations and better signal to noise ratio according to one embodiment. The process illustrated in FIG. 3 relies on several assumptions. First, an iterative scheme performs in a reasonable SNR range for turbo equalization. This is to ensure that turbo equalization works during the simulation. In other words the BER or SER improves with each iteration. Second, while the errors on each iteration decrease, the difference delta (δ) in the soft value after each iteration also decreases with the same trend. Third, the turbo equalization scheme of one embodiment is able to correct erroneous data. The number of corrected errors can be obtained by calculating δ. A detailed discussion of the second and third assumptions is provided below with regards to FIGS. 5 and 7.

The first step of the process is to perform the first iteration of turbo equalization. This is illustrated at step 310. Also at step 310, a variable such as n, representative of the number of iterations performed, is set to one. At step 315 the soft outputs of all the data bits from the first iteration are saved. In one embodiment, the soft output includes log likelihood ratios of the detected output, that is the probability of whether each output bit is ‘1’ or ‘0’. However, other soft outputs can be used.

At step 320 a second iteration of turbo equalization is performed. At this step, n is incremented to n+1, representative of the next iteration of the turbo equalization. The soft value of this iteration is then saved. This is illustrated at step 325.

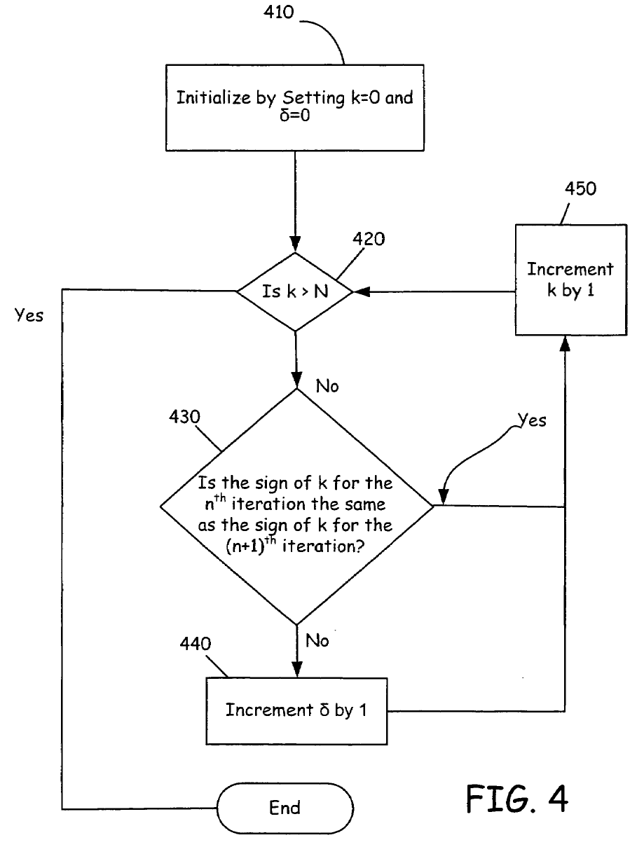

At step 330 the delta (δ) of the soft values between the nth iteration and the (n+1)^{th} iteration are computed. One process for computing the δ is discussed with respect to FIG. 4. FIG. 4 is a flow diagram illustrating a process for determining the δ between the n^{th} and (n+1)^{th} iteration according to one embodiment. At step 410 variables k and δ are set to zero . The variable k is an index representing a bit position in the block currently being evaluated.

At step 420 the process determines if k>N. Where N represents total size of the data block. If k>N then the comparison process is over. If not, the process proceeds to block 430. At block 430, the sign of k^{th} bit from the n^{th} iteration is compared with the sign of the k^{th} bit from the (n+1)^{th} iteration.

If the sign of the k^{th} bit for the nth iteration is the same as the sign of the k^{th} bit for the (n+1)^{th} iteration the process proceeds to step 450. If the sign is not the same then the process proceeds to step 440. At step 440, δ is incremented by one. When δ is incremented it is indicative that a data error has been corrected in the (n+1)^{th} iteration. Once δ has been incremented the process proceeds to step 450. At step 450 k is incremented by one to move to the next bit in the data block. This process of steps 420-450 repeats until k>N. The process ends at step 460.

Returning now to FIG. 3, at step 340 the system determines if the calculated δ exceeds a predetermined criteria or value for stopping the turbo equalization. In one embodiment the stopping criteria is δ=0. However other stopping criteria can be used such as δ=1 or 2. If δ does not equal the stopping criteria the early termination process proceeds to step 350. At step 350 the soft values for the nth iteration are discarded and the iteration variable n is set to n=n+1. The process then moves forward to step 320 and performs a next iteration of turbo equalization, this time comparing δ between the previous iteration and the present iteration. This process repeats until δ equals the stopping criteria.

If δ equals the stopping criteria the process proceeds to step 360. At step 360, the soft values for the most recent iteration are output. The values are output to a hard decoder 560 of FIG. 5.

FIG. 5 is a block diagram illustrating a simulated layout of a turbo equalizer 500 according to one embodiment. Data blocks containing bits having values of ±1 are generated and input at 510. Block 512 employs a recursive systematic convolutional code (RSC) as an outer encoder. In one embodiment, the generator matrix for the RSC encoder is (31, 33). The encoded data is then interleaved by a random interleaver 514. The random interleaver 514 rearranges the elements of its input vector using a pseudo-random permutation. An initial seed parameter initializes the random number generator that the block uses to determine the permutation. The interleaver 514 is predictable for a given seed, but different seeds produce different permutations. Interleaver 514 is used to prevent any burst error if the signal, and thus improve accuracy.

The inner encoder 520 of the simulated turbo equalizer 500 comprises a precoder 522 with generator matrix of g(D)=1/D², and a PR4 channel 526. An additive white Gaussian noise (AWGN) is added to simulate the linear noise in different SNR ranges. The decoding of the output of the outer encoder 512 and inner encoder 520 is illustrated by iterative decoder 530. In one embodiment the decoding is performed according to the methods described in, T. Souvignier et al., “Turbo Decoding for Partial Response Channels,” in IEEE Trans on Commun., vol. 48, no. 8, August 2000. p. 1297-1308. However, other methods can be used.

After each iteration, the soft output 540 from the decoder 530 is analyzed using a dynamic ET processor 550 to decide when to terminate the iteration process. In one embodiment, the process used by dynamic ET processor 550 includes the process discussed with respect to FIGS. 3 and 4. Using the final, terminated soft outputs, block 560 makes a hard decision as to the value of each data bit. The soft output produced after each iteration of iterative decoder 530 can have any suitable format. For example, the soft output can include, for each bit of the multiple-bit value (such as +1 or −1) and likelihood that the value is correct. Alternatively, the soft output can include a range of signal values, wherein the sign represents the decoded value and the magnitude represents the likelihood the value is correct. For example, the soft output can range from '10 to +10. However other values and formats can be used.

The following is a discussion of an illustrative set of data used to determine whether the error after each iteration decreases, and if the sum of change of sign on each iteration also decreases with the same trend. A simulation with 1500 blocks of data is simulated and studied. The signal to noise ration (SNR) was set at 3 dB, and the data block size was set at 4000. For each block, 7 iterations were performed and processed. After processing, the mean of total error and mean of total corrected error after each iteration was calculated, as illustrated in Table 1. The corrected error was computed by subtracting the error of the current iteration from the error of the previous iteration.

TABLE 1

| | | Mean of total corrected |
|---|---|---|
| Iteration No | Mean of total error | error |
| 1 | 234.36 | |
| 2 | 98.56 | 135.8 |
| 3 | 42.00 | 56.56 |
| 4 | 20.88 | 21.12 |
| 5 | 10.78 | 10.1 |
| 6 | 6.50 | 4.28 |
| 7 | 4.58 | 1.92 |

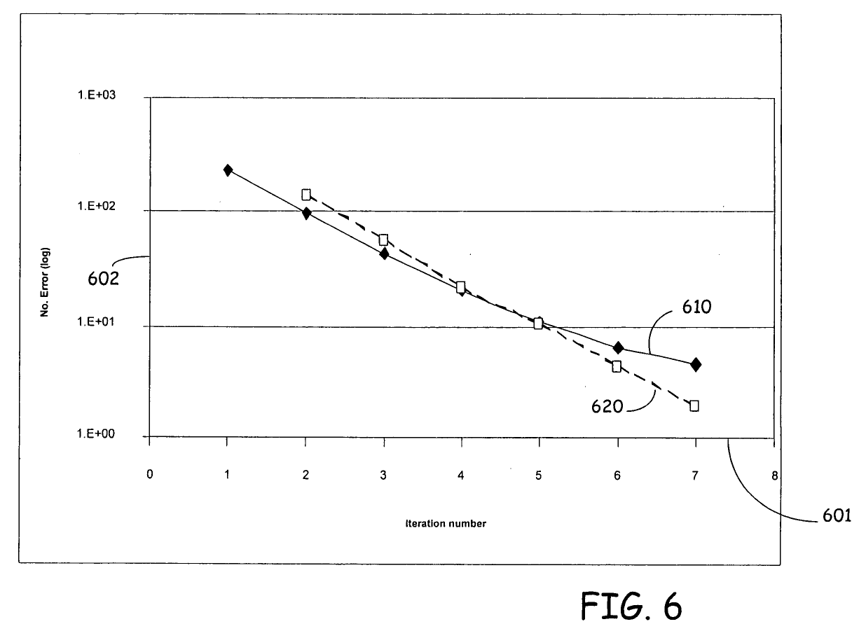

FIG. δ is a plot illustrating in a log scale the values of Table 1. In FIG. 6, x-axis 601 represents the number of iterations and y-axis 602 represents the number of corrected errors. It can be seen that mean of error (solid line 610) and mean of corrected error (dashed line 620) are close to each other and have the same decreasing trend. FIG. 6 illustrates that the delta of corrected error is a good indicator to use when deciding when to terminate the iteration.

TABLE 2

| | | | Reliability |
|---|---|---|---|
| | | | 100% − (Column |
| | Mean of (δ - actual | Mean of | 2/Column |
| After Iteration | corrected errors) | corrected error | 3 * 100)% |
| 2 | 12.76 | 135.8 | 90.60% |
| 3 | 2.40 | 56.56 | 95.76% |
| 4 | 0.63 | 21.12 | 97.02% |
| 5 | 0.21 | 10.1 | 97.92% |
| 6 | 0.11 | 4.28 | 97.43% |
| 7 | 0.06 | 1.92 | 96.88% |

Table 2 illustrates the effectiveness of the flipping sign technique of the embodiments discussed above. In Table 2, the second column represents the mean of δ (sum of flipping sign on each soft values compared with the previous iteration). For example, after 2^{nd} iteration, the mean of difference is 12.7578. This means on average, there are about 13 more errors predicted than the actual errors corrected during 2^{nd} iteration. The fourth translates information in the second column into a measure of the reliability of the technique with respect to the mean of corrected error.

From Table 2, it can be seen that the technique of monitoring the flipping signs closely relates to the actual corrected errors. The mean of difference is worst at the 2^{nd} iteration. This is because during the first few iterations, the soft output is less certain, and therefore not as reliable. Nevertheless, the reliability at the 2nd iteration achieves a 90.6% reliability. Outside of the 2^{nd} iteration, the reliability increases to more than 95%. This illustrates that the disclosed flipping sign technique is highly reliable for corrected error prediction.

FIG. 7 is a plot illustrating the sector error rate (SER) of the dynamic ET process shown in FIGS. 3 and 5 with SER after different numbers of iterations (NOI). Axis 702 represents SNR in dB, and axis 704 represents SER. The simulation was performed with an SNR from 2 dB to 4 dB. The simulation assumed that the HDD controller in had the capability of correcting 16 data bit errors. That is, if the hard output of the dynamic ET process had more than 16 bit errors, it was considered that this sector failed and was not able to be corrected.

For the stopping criteria, the simulation stopped when δ was found to be two consecutive errors. This is a rather conservative stopping point. If it is desired to accept a trade off between NOI and SER, the stopping condition of δ can be one, zero or some other number.

The SER was obtained by dividing the total failed sectors with the total number of sector (data) blocks simulated. The SER after 1 to 7 iterations are computed and plotted in FIG. 7 which are labeled “ITER1” to “ITER7”. This was then compared with the SER with the dynamic ET process shown by line 750. It can be seen from FIG. 7 that with the dynamic ET process, the SER is as good as the performance after seven iterations at 4 dB.

The average iteration used for the dynamic ET process on different SNR is shown in Table 3:

TABLE 3

| | | Increment w.r.t.7 |
|---|---|---|
| SNR(dB) | Average Iteration | iterations (%) |
| 2 | 6.48 | 7.43% |
| 3 | 5.32 | 24.00% |
| 4 | 4.75 | 32.14% |

For poorer SNR, the average number of iterations needed is larger. At high SNR, the average number of iterations needed is less. This is reasonable, as less iterations are needed to achieve good results at high SNR region. This illustrates that the dynamic ET process is able to dynamically choose the required iteration to achieve satisfactory results. The dynamic ET process of the present disclosure is able to reduce the NOI significantly. The percentage of saving is calculated and illustrated in the third column of Table 3. At 4 dB, we are able to reduce the NOI by as much as 32.14% with respect to 7 iterations, and achieve the same SER performance. As mentioned before, additional iterations directly translate into additional power and time consumed. Therefore, the dynamic ET process is able to reduce the power and processing time for a turbo equalization scheme significantly.

It is to be understood that even though numerous characteristics and advantages of various embodiments of the invention have been set forth in the foregoing description, together with details of the structure and function of various embodiments of the invention, this disclosure is illustrative only, and changes may be made in detail, especially in matters of structure and arrangement of parts within the principles of the present disclosure to the full extent indicated by the broad general meaning of the terms in which the appended claims are expressed. For example, the particular elements may vary depending on the particular application for the turbo equalization system while maintaining substantially the same functionality without departing from the scope and spirit of the present disclosure. In addition, although the embodiments described herein is directed to an early termination process in a data storage system, it will be appreciated by those skilled in the art that the teachings of the present disclosure can be applied to other systems or communication channels employing turbo equalization, without departing from the scope and spirit of the present disclosure.

What is claimed is:

1. A process comprising iteratively decoding a communication channel output until a function based on a number of errors corrected between subsequent iterations reaches a stopping value.

2. The process of claim 1 wherein the communication channel output comprises a sequence of multiple bit data blocks and wherein the process comprises:
(a) for each data block iteratively decoding the data block;
(b) identifying a number of the bits in the data block that are altered with each iteration at step (a); and
(c) terminating step (a) and outputting a decoded data block when the number of bits altered reaches the stopping value.

3. The process of claim 2 wherein:
step (a) comprises, with each iteration, generating a signed value for each bit of the data block; and
step (b) comprises, after each iteration, comparing the sign of each bit of the data block with the sign of a respective bit of the data block from an immediately prior iteration.

4. The process of claim 3 wherein the step (a) comprises, for each iteration, generating a soft output, which comprises the signed values for the data block and respective likelihoods that the signed values are correct.

5. The process of claim 3 wherein step (a) comprises, for each bit of the data block, generating a soft output that comprises the signed value and a likelihood that the soft output is correct.

6. The process of claim 1 wherein the stopping value is one

7. The process of claim 1 wherein the stopping value is zero.

8. A decoder comprising an iterative decode function, which terminates as a function of a number of errors corrected between subsequent iterations of the decode function.

9. The decoder of claim 8 wherein the decode function is adapted to receive a sequence of multiple bit data blocks and:
(a) iteratively decoding the data block according to the iterative decode function;
(b) identify a number of the bits in the data block that are altered with each iteration at step (a); and
(c) terminate step (a) and output a decoded data block when the number of bits altered reaches a stopping value.

10. The decoder of claim 9 wherein the decode function is adapted to generate with each iteration of step (a), a signed value for each bit of the data block; and, after each iteration, compare the sign of each bit of the data block with the sign of a respective bit of the data block from an immediately prior iteration.

11. The decoder of claim 10 wherein the decode function generates, for each iteration, a soft output, which comprises the signed values for the data block and respective likelihoods that the signed values are correct.

12. The decoder of claim 9 wherein in the stopping value is in a range from zero to two.

13. A data storage device, comprising:
a storage medium;
a write channel coupled to communicate with the storage medium; and
a read channel coupled to communicate with the storage medium and comprising a decoder that comprises an iterative decode function, which terminates as a function of a number of errors corrected between subsequent iterations of the decode function.

14. The data storage device of claim 13 wherein the data comprises a sequence of multiple bit data blocks, and wherein the decoder is configured to:
iteratively decode each data block in the data blocks;
identify a number of errors corrected in each iteration; and
terminate the iterative decoding if the number of errors exceeds a stopping value.

15. The data storage device of claim 14 wherein the decoder identifies the number of errors corrected in each iteration by determining a number of bits in the data block that are altered at each iteration.

16. The data storage device of claim 15 wherein the decoder generates a signed value for each bit of each data block and compares the sign of each bit of the data block with the sign of a corresponding data bit from an immediately prior iteration.

17. The data storage device of claim 16 wherein the decoder generates a soft output, which comprises the signed values for the data block and respective likelihoods that the signed values are correct.
